(19) United States
(12) Patent Application Publication
(10) Pub. No.: US 2026/0190776 A1
(43) Pub. Date: Jul. 2, 2026

(54) DISPLAY DEVICE, METHOD OF MANUFACTURING THE SAME, AND ELECTRONIC DEVICE

(71) Applicant: Samsung Display Co., Ltd., Yongin-Si (KR)

(72) Inventors: JEONGSOO KIM, Yongin-si (KR); HYUNGGUEN YOON, Yongin-si (KR)

(21) Appl. No.: 19/268,608

(22) Filed: Jul. 14, 2025

(30) Foreign Application Priority Data
Dec. 26, 2024 (KR) 10-2024-0197061

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes a plurality of pixels arranged on a substrate, a thin film transistor arranged in each of the plurality of pixels, a passivation layer covering the thin film transistor, a pixel-defining film defining a plurality of light-emitting areas and including a light-absorbing material, a light-emitting element including a pixel electrode arranged on the passivation layer corresponding to the plurality of light-emitting areas defined by the pixel-defining film, an encapsulation layer sealing the light-emitting element, and a color filter layer overlapping the plurality of light-emitting areas and including at least one color filter arranged on the encapsulation layer. A top surface of the pixel electrode includes an electrode surface pattern, and a peak-to-valley of the electrode surface pattern is in a range from about 30 nanometers to about 50 nanometers.

### CROSS-REFERENCE TO RELATED APPLICATION

This application claims priority under 35 U.S.C. § 119 to Korean Patent Application No. 10-2024-0197061, filed on Dec. 26, 2024, in the Korean Intellectual Property Office, the disclosure of which is incorporated by reference herein in its entirety.

### BACKGROUND

### 1. Field

Embodiments of the present disclosure relate to a display device, a method of manufacturing the same, and an electronic device including the display device.

### 2. Description of the Related Art

The display device may display an image through a light-emitting element included in the display device. The display devices are applied to various electronic devices such as smartphones, digital cameras, laptop computers, navigation systems, televisions, etc., and are being developed in various forms. Recently, the development of the technology has been actively underway to enable the display devices to provide highly visible and visually clear screens.

### SUMMARY

The present disclosure provides a display device having a highly visible and visually clear screen, a method of manufacturing the display device, and an electronic device including the display device.

According to an embodiment of the present disclosure, a display device includes a plurality of pixels arranged on a substrate, a thin film transistor arranged in each of the plurality of pixels, a passivation layer covering the thin film transistor, a pixel-defining film defining a plurality of light-emitting areas and including a light-absorbing material, wherein each of the plurality of pixels includes at least one light-emitting area, a light-emitting element including a pixel electrode arranged on the passivation layer corresponding to the plurality of light-emitting areas defined by the pixel-defining film, an encapsulation layer sealing the light-emitting element, and a color filter layer overlapping the plurality of light-emitting area and including at least one color filter arranged on the encapsulation layer. A top surface of the pixel electrode includes an electrode surface pattern, and a peak-to-valley of the electrode surface pattern is in a range from about 30 nanometers to about 50 nanometers.

A top surface of the passivation layer corresponding to the plurality of light-emitting areas may include a passivation layer surface pattern, and the electrode surface pattern provided on the top surface of the pixel electrode may follow the passivation layer surface pattern. A peak-to-valley of the passivation layer surface pattern may be in a range from about 50 nanometers to about 100 nanometers.

An entire top surface of the passivation layer may include the passivation layer surface pattern.

The passivation layer surface pattern may include, on the top surface of the passivation layer, a different pattern shape for each of the pixels arranged in rows or columns, or a different pattern shape for each of the plurality of light-emitting areas.

The passivation layer surface pattern and the electrode surface pattern may include groove patterns including a dented portion, or rib patterns including a protruding portion.

Each of the passivation layer surface pattern and the electrode surface pattern may include at least one of a dot pattern, a line pattern, or a grid pattern.

Each of the passivation layer surface pattern and the electrode surface pattern may have an arbitrary random pattern shape, a non-periodic pattern shape having no repetitive period, or a randomly arranged random number pattern shape.

A top surface of the passivation layer may be flat, and the pixel electrode having the electrode surface pattern may be arranged on the passivation layer having the flat top surface.

The pixel electrode may include a reflective electrode including a metal having a high reflectance arranged on the passivation layer, and a transparent electrode including a conductive metal oxide arranged on the reflective electrode.

The passivation layer may include a first passivation layer covering the thin film transistor and including an organic material, and a second passivation layer arranged on the first passivation layer and including an organic material. The pixel electrode may be arranged on a top surface of the second passivation layer.

The display device may further include a touch sensing layer including a touch electrode between the encapsulation layer and the color filter layer.

The color filter layer may further include a light-shielding layer overlapping the pixel-defining film and including a hole corresponding to the color filter, and a planarization layer covering the color filter and the light-shielding layer, including an organic material, and planarizing a top surface of the color filter.

According to an embodiment of the present disclosure, a method of manufacturing a display device includes forming a thin film transistor in each of a plurality of pixels arranged on a substrate, forming a passivation layer covering the thin film transistors, forming a pixel electrode including an electrode surface pattern and arranged on the passivation layer corresponding to a light-emitting area, forming a pixel-defining film including a light-absorbing material and arranged on the passivation layer to define the light-emitting area, forming a light-emitting layer on the pixel electrode corresponding to the light-emitting area, forming a common electrode covering a top surface of the light-emitting layer, forming an encapsulation layer sealing a light-emitting element including the pixel electrode, the light-emitting layer and the common electrode, and forming a color filter layer including at least one color filter overlapping the light-emitting area and arranged on the encapsulation layer. A peak-to-valley of the electrode surface pattern is in a range from about 30 nanometers to about 50 nanometers.

The forming of the pixel electrode including the electrode surface pattern may include forming a passivation layer surface pattern using an imprint method on the passivation layer corresponding to the light-emitting area, and forming the electrode surface pattern of the pixel electrode using the passivation layer surface pattern on the passivation layer corresponding to the light-emitting area.

The forming of the passivation layer surface pattern may include contacting a mold including a pattern corresponding to the passivation layer surface pattern with a top surface of the passivation layer and imprinting the pattern of the mold on the top surface of the passivation layer. A peak-to-valley of the passivation layer surface pattern may be in a range from about 50 nanometers to about 100 nanometers.

The passivation layer surface pattern may be formed on an entire top surface of the passivation layer.

The forming of the passivation layer surface pattern may include forming, on a top surface of the passivation layer, a different pattern shape for each of the pixels arranged in a row or a column, or a different pattern shape for each light-emitting area.

According to an embodiment of the present disclosure, an electronic device includes a pixel circuit arranged in a pixel on a substrate and including a thin film transistor, a passivation layer covering the thin film transistor, a pixel-defining film defining a light-emitting area and including a light-absorbing material, a light-emitting element including a pixel electrode arranged on the passivation layer corresponding to the light-emitting area defined by the pixel-defining film, an encapsulation layer sealing the light-emitting element, a color filter layer including at least one color filter arranged on the encapsulation layer and overlapping the light-emitting area, a controller configured to apply a signal to the pixel circuit, and a power module configured to apply power to the controller. A top surface of the pixel electrode includes an electrode surface pattern, and a peak-to-valley of the electrode surface pattern is in a range from about 30 nanometers to about 50 nanometers.

A top surface of the passivation layer corresponding to the light-emitting area may include a passivation layer surface pattern, and the electrode surface pattern provided on the top surface of the pixel electrode may follow the passivation layer surface pattern. A peak-to-valley of the passivation layer surface pattern may be in a range from about 50 nanometers to about 100 nanometers.

An entire top surface of the passivation layer may include the passivation layer surface pattern.

### BRIEF DESCRIPTION OF THE DRAWINGS

The above and other aspects will become apparent and more readily appreciated from the following description of the embodiments taken in conjunction with the accompanying drawings.

FIG. 1 is a schematic plan view of an electronic device according to an embodiment.

FIG. 2 is a perspective view showing a folding state of a foldable display device according to an embodiment.

FIG. 3 is a perspective view showing an unfolding state of the foldable display device of FIG. 2.

FIG. 4 is a perspective view showing a display device included in an electronic device according to an embodiment.

FIG. 5 is a cross-sectional view of the display device of FIG. 4 viewed from a side.

FIG. 6 is a plan view showing a display layer of a display device according to an embodiment.

FIG. 7 is a plan view showing the arrangement of light-emitting regions and color filters of the display device of FIG. 5.

FIG. 8 is a cross-sectional view taken along a line VIII-VIII′ of FIG. 7.

FIG. 9A is an enlarged cross-sectional view of a portion IX of FIG. 8 and illustrates a first surface pattern of a second passivation layer.

FIG. 9B is an enlarged cross-sectional view of a portion IX of FIG. 8 and illustrates a second surface pattern of a pixel electrode and a method of forming the same according to an embodiment.

FIG. 10A is a cross-sectional view showing a first surface pattern of a second passivation layer.

FIG. 10B is a cross-sectional view showing a second surface pattern of a pixel electrode and a method of forming the same according to an embodiment.

FIG. 11A and FIG. 11B show photographs of a first surface pattern and a second surface pattern according to an embodiment of FIG. 10A and FIG. 10B.

FIGS. 12A to 12G are plan views showing various shapes and arrangements of the first surface pattern described in FIG. 7.

FIG. 13A, FIG. 13B and FIG. 13C are cross-sectional views showing a surface pattern of a pixel electrode and a method of forming the same according to an embodiment.

FIG. 14 is a block diagram of an electronic device according to embodiments.

FIG. 15 is a schematic diagram of an electronic device according to various embodiments.

### DETAILED DESCRIPTION

The disclosure may have various modifications and various embodiments, and thus particular embodiments will be illustrated in the drawings and described in detail in the following detailed description. Effects and features of the disclosure, and methods for achieving them will become clear with reference to the embodiments described in the following detailed description together with the accompanying drawings. However, the disclosure is not limited to the embodiments disclosed herein and may be implemented in various forms.

In the following disclosure, the terms, such as first, second, etc., have been used to distinguish one component from other components, and the components are not limited by the terms.

In the following disclosure, a singular form may include plural forms unless apparently indicated otherwise in the context of the disclosure.

In the following disclosure, the terms, such as “include”, “have”, or the like, are intended to mean that there are features, or components, described herein, but do not preclude the possibility of adding one or more other features or components.

In the following disclosure, when a portion, such as a film, a region, a component, etc., is referred to as being on or above another portion, the portion may be directly on another portion, or indirectly on another portion with an intervening portion being presented therebetween.

In the following disclosure, terms, such as connect or combine, do not necessarily imply a direct and/or fixed connection or combination of two components and do not exclude the indirect connection or combination with an intervening component being presented between the two components, unless the context clearly indicates otherwise.

In the drawings, the size of components may be exaggerated or reduced for convenience of description. That is to say, as the size and thickness of each component shown in the drawings are arbitrarily depicted for convenience of description, the disclosure is not necessarily limited to the size of components illustrated in the drawings.

In the following disclosure, an x-axis, a y-axis, and a z-axis are not limited to three axes on an orthogonal coordinate system, and may be interpreted in a broad sense including them. That is to say, the x-axis, the y-axis, and the z-axis may be orthogonal to each other, but may also refer to different directions that are not orthogonal to each other.

In the following disclosure, a scan driver, a scan signal, a scan control signal, a scan line, and a scan control line may also be referred to as a gate driver, a gate signal, a gate control signal, a gate line, and a gate control line.

Hereinafter, embodiments of the disclosure will be described in detail with reference to the accompanying drawings. When describing the embodiments with reference to the drawings, identical or corresponding components are given the same drawing reference numerals and redundant descriptions thereof will be omitted.

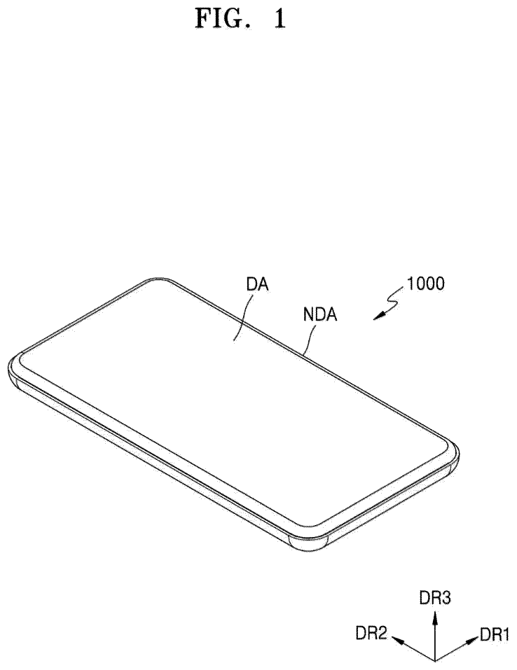

FIG. 1 is a schematic plan view of an electronic device according to an embodiment.

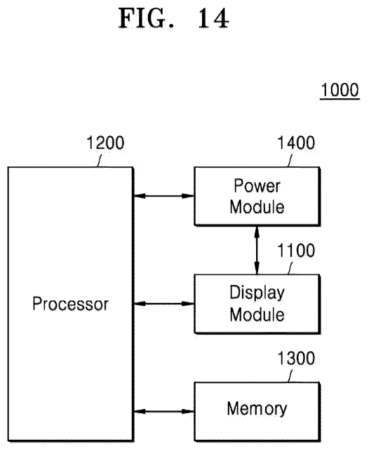

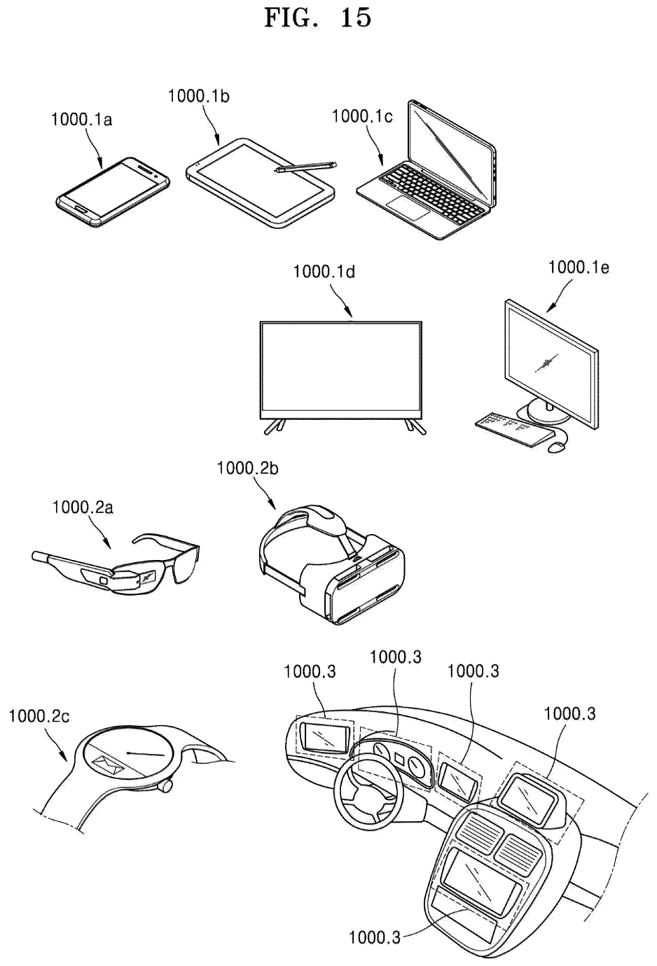

Referring to FIG. 1, an electronic device 1000 may refer to any electronic device that provides a display screen. For example, a television, a laptop computer, a monitor, a billboard, an Internet of Things (IoT), a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation system, a game console, a digital camera, a camcorder, etc., which provides a display screen, may be implemented as the electronic device 1000. Hereinafter, a smart phone is taken as an example of the electronic device 1000, but the disclosure is not limited thereto. Additional details of the electronic device 1000 may be further described with reference to FIG. 14.

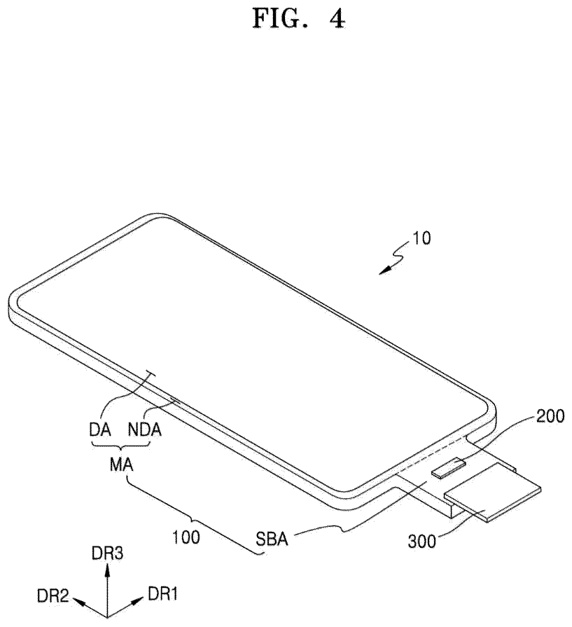

The electronic device 1000 may include a display device 10 providing a display screen, as depicted in FIG. 4. Examples of the display device may include inorganic light-emitting diode display devices, organic light-emitting display devices, quantum dot light-emitting display devices, plasma display devices, field emission display devices, etc. Hereinafter, an organic light-emitting diode is used as an example of a display device, but the disclosure is not limited thereto.

The shape of the electronic device 1000 may be modified in various ways. For example, the electronic device 1000 may have various shapes such as a horizontally elongated rectangle, a vertically elongated rectangle, a square, a rectangle with rounded corners (vertices), other polygons, a circle, etc. The shape of a display area DA of the electronic device 1000 may also be similar to the overall shape of the electronic device 1000. In FIG. 1, the electronic device 1000 having a rectangular shape elongated in a second direction DR2 is shown.

The electronic device 1000 may include the display area DA and a non-display area NDA. The display area DA may be an area where an image is displayed, and the non-display area NDA may be an area where an image is not displayed. The display area DA may also be referred to as an active area, and the non-display area NDA may also be referred to as an inactive area. The display area DA may generally occupy the center of the electronic device 1000, and the non-display area NDA may surround at least one side of the display area DA.

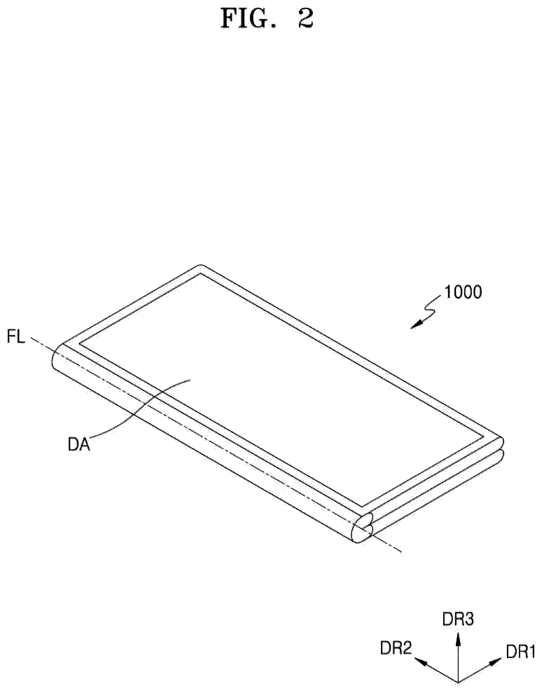

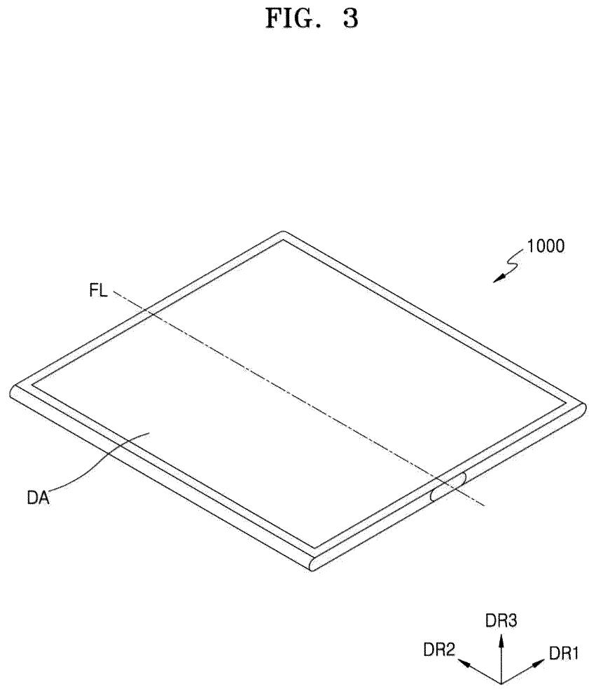

FIG. 2 is a perspective view showing a folding state of a foldable display device according to an embodiment. FIG. 3 is a perspective view showing an unfolding state of the foldable display device of FIG. 2.

Referring to FIGS. 2 and 3, the electronic device 1000 according to an embodiment may be a foldable display device. The foldable electronic device 1000 may be folded with respect to a folding axis FDL. The display area DA may be positioned on an outer and/or inner side of the foldable electronic device 1000. For example, the display areas DA according to an embodiment are respectively arranged on both the outer and inner sides of the foldable electronic device 1000, as depicted in FIGS. 2 and 3.

FIG. 4 is a perspective view showing a display device included in an electronic device according to an embodiment.

Referring to FIG. 4, the electronic device 1000 according to an embodiment may include the display device 10. The display device 10 may provide a screen through which an image is displayed on the electronic device 1000. The display device 10 may have a planar shape similar to the electronic device 1000. For example, the display device 10 may have a shape similar to a rectangle having a short side in a first direction DR1 and a long side in the second direction DR2. A corner where the short side in the first direction DR1 meets the long side in the second direction DR2 meet may be rounded to have a curvature. However, the disclosure is not limited thereto, and the corner may also be formed at a right angle. The planar shape of the display device 10 is not limited to a rectangle, and may be formed similarly to other polygons, a circle, or an oval.

The display device 10 may include a display panel 100, a display driving unit 200, and a circuit board 300.

The display panel 100 may include a main area MA and a sub area SBA.

The main area MA may include the display area DA including pixels displaying an image, and the non-display area NDA arranged around the display area DA. The display area DA may emit light from a plurality of light-emitting areas or a plurality of opening areas in the pixels. For example, the display panel 100 may include a pixel circuit including switching elements, a pixel-defining film defining a light-emitting area or an opening area, and a self-light-emitting element.

For example, the self-light-emitting element may include, but not limited to, at least one of an organic light-emitting diode (OLED) including an organic light-emitting layer, a quantum dot LED including a quantum dot light-emitting layer, an inorganic LED including an inorganic semiconductor, and a micro light-emitting diode (micro LED).

The non-display area NDA may be outside the display area DA. The non-display area NDA may be defined as an edge area of the main area MA of the display panel 100. The non-display area NDA may include a scan driver (not shown) that supplies scan signals to scan lines, and fan out lines (not shown) that connect the display driving unit 200 to the display area DA.

A sub-area SBA may be an area extending from a side of the main area MA. The sub-area SBA may include a flexible material capable of bending, folding, rolling, etc. For example, when the sub-area SBA is bent, the sub-area SBA may overlap the main area MA in a thickness direction (e.g., a third direction DR3). The sub-area SBA may include the display driving unit 200 and a pad portion connected to the circuit board 300. However, the disclosure is not limited thereto. For example, the sub-area SBA may be omitted, and the display driving unit 200 and the pad portion may be arranged in the non-display area NDA.

The display driving unit 200 may output signals and voltages for driving the display panel 100. The display driving unit 200 may supply data voltages to data lines. For example, the display driving unit 200 may include a data driver that may supply data voltages to data lines. The display driving unit 200 may supply a power voltage to a power line and supply a scan control signal to a scan driver. The display driving unit 200 may be formed as an integrated circuit (IC) and may be mounted on the display panel 100 in a chip on glass (COG) manner, a chip on plastic (COP) manner, or an ultrasonic bonding manner. For example, the display driving unit 200 may be arranged in the sub-area SBA and may overlap the main area MA in a thickness direction when the sub-area SBA is bent. However, the disclosure is not limited thereto. For example, the display driving unit 200 may be mounted on the circuit board 300.

The circuit board 300 may be attached to the pad portion of the display panel 100 using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

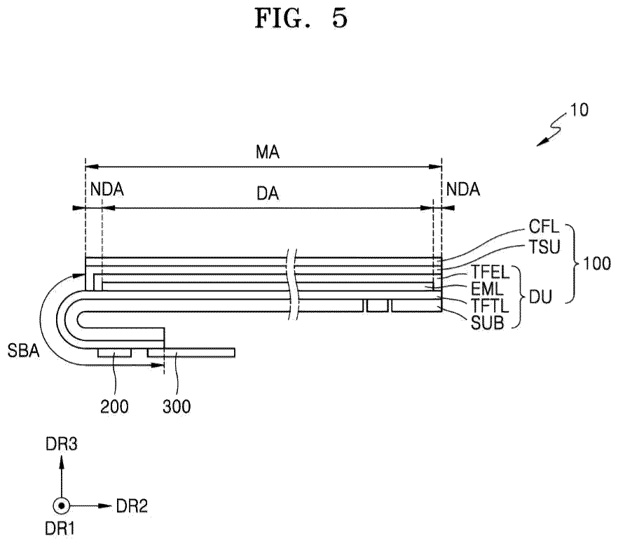

FIG. 5 is a cross-sectional view of the display device of FIG. 4 viewed from a side.

Referring to FIG. 5, the display panel 100 may include a display layer DU, a touch sensing layer TSU, and a color filter layer CFL. The display layer DU may include a substrate SUB, a thin film transistor layer TFTL, a light-emitting element layer EML, and an encapsulation layer TFEL.

The substrate SUB may be a base substrate or a base member. The substrate SUB may be a flexible substrate capable of bending, folding, rolling, etc. For example, the substrate SUB may include, but not limited to, a polymer resin such as polyimide (PI). For example, the substrate SUB may include a glass material or a metal material.

The thin film transistor layer TFTL may be arranged on the substrate SUB. The thin film transistor layer TFTL may include a plurality of thin film transistors that form a pixel circuit in each of the pixels. The thin film transistor layer TFTL may further include scan lines, data lines, power lines, scan control lines, fan out lines connecting the display driving unit 200 to the data lines, and lead lines connecting the display driving unit 200 to the pad portion. Each of thin film transistors may include a semiconductor region, a source electrode, a drain electrode, and a gate electrode.

The thin film transistor layer TFTL may be arranged in the display area DA, the non-display area NDA, and the sub-area SBA. Thin film transistors, scan lines, data lines, and power lines in the thin film transistor layer TFTL, which correspond to each pixel, may be arranged in the display area DA. Scan control lines and fan out lines of the thin film transistor layer TFTL may be arranged in the non-display area NDA. Lead lines of the thin film transistor layer TFTL may be arranged in the sub-area SBA.

The light-emitting element layer EML may be arranged on the thin film transistor layer TFTL. The light-emitting element layer EML may include a plurality of light-emitting elements that emit light, including a pixel electrode, a common electrode, and a light-emitting layer, and a pixel-defining film that defines light-emitting regions. The plurality of light-emitting elements of the light-emitting element layer EML may be arranged in the display area DA.

In an embodiment, the light-emitting layer may be an organic light-emitting layer including an organic material. The light-emitting layer may include a hole transporting layer, an organic light-emitting layer, and an electron transporting layer. When the pixel electrode receives a voltage through the thin film transistors of the thin film transistor layer TFTL (e.g., through the pixel circuit in each of the pixels) and the common electrode receives a cathode voltage, holes and electrons may move to the organic light-emitting layer through the hole transport layer and the electron transport layer, respectively, and emit light by combining the holes and the electrons with each other in the organic light-emitting layer.

However, the disclosure is not limited thereto. For example, the light-emitting element layer EML may include a quantum dot light-emitting diode including a quantum dot light-emitting layer, an inorganic light-emitting diode including an inorganic semiconductor, or a micro light-emitting diode.

A touch sensing layer TSU may be arranged on the encapsulation layer TFEL. The touch sensing layer TSU may include a plurality of touch electrodes for detecting a user's touch in a capacitive manner, and touch lines connecting the plurality of touch electrodes to a touch driving unit. For example, the touch sensing layer TSU may sense the user's touch in a mutual capacitance manner or a self-capacitance manner.

The color filter layer CFL may be arranged on the touch sensing layer TSU. The color filter layer CFL may include a plurality of color filters which corresponds to a plurality of light-emitting regions. Each color filter may selectively transmit light of a specific wavelength and block or absorb light of other wavelengths. The color filter layer CFL may absorb a part of the light coming from the outside of the display device 10 and reduce reflected light due to external light. Thus, the color filter layer CFL may prevent color distortion due to external light reflection.

As the color filter layer CFL is arranged directly on the touch sensing layer TSU, the display device 10 may not require a separate substrate for the color filter layer CFL. Thus, the thickness of the display device 10 may be reduced.

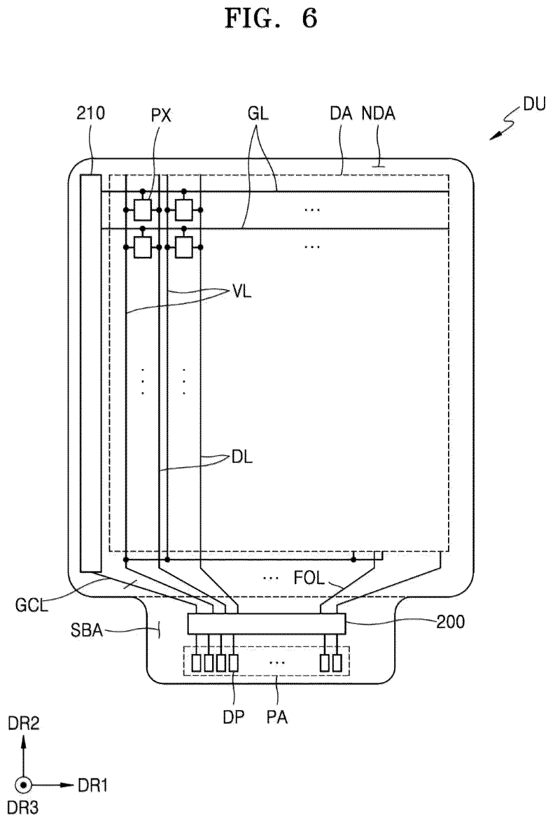

FIG. 6 is a plan view showing a display layer of a display device according to an embodiment.

Referring to FIG. 6, the display layer DU may include the display area DA and the non-display area NDA.

The display area DA may be arranged in the center of the display panel 100. A plurality of pixels PX, a plurality of scan lines GL, a plurality of data lines DL, and a plurality of power lines VL may be arranged in the display area DA. Each of the plurality of pixels PX may be defined as a minimum unit that emits light.

The plurality of scan lines GL may supply scan signals received from a scan driver 210 to the plurality of pixels PX. The plurality of scan lines GL may extend in the first direction DR1 and may be spaced apart from each other in the second direction DR2 intersecting the first direction DR1.

The plurality of data lines DL may supply a data voltage received from the display driving unit 200 or a data driver, which is included in the display driving unit 200 or separate from the display driving unit 200, to the plurality of pixels PX. The plurality of data lines DL may extend in the second direction DR2 and may be spaced apart from each other in the first direction DR1.

The plurality of power lines VL may supply a power voltage received from the display driving unit 200 to the plurality of pixels PX. The power voltage supplied to the plurality of pixels PX through the plurality of power lines VL may include at least one of a driving voltage (or a first voltage ELVDD), an initialization voltage, a reference voltage, and a low-potential voltage (or a second voltage ELVSS). The plurality of power lines VL may extend in the second direction DR2 and may be spaced apart from each other in the first direction DR1.

The non-display area NDA may surround the display area DA. The scan driver 210, fan out lines FOL, and scan control lines GCL may be arranged in the non-display area NDA. The scan driver 210 may generate a plurality of scan signals based on a scan control signal and sequentially supply the plurality of scan signals to the plurality of scan lines GL in a preset order.

The sub-area SBA may include the display driving unit 200 and a pad area PA.

The display driving unit 200 may output signals and voltages for driving the display panel 100 to the fan out lines FOL. The data driver, which is included in the display driving unit 200 or separate from the display driving unit 200, may supply a data voltage to the data line DL through the fan out lines FOL. The data voltage may be supplied to the plurality of pixels PX to control the brightness of the plurality of pixels PX. The display driving unit 200 may supply a scan control signal to the scan driver 210 through the scan control line GCL.

The pad area PA may include a plurality of display pad portions DP. The plurality of display pad portions DP may be connected to a processor 1200 in FIG. 14 through the circuit board 300. The plurality of display pad portions DP may be connected to the circuit board 300 to receive digital video data and supply the digital video data to the display driving unit 200.

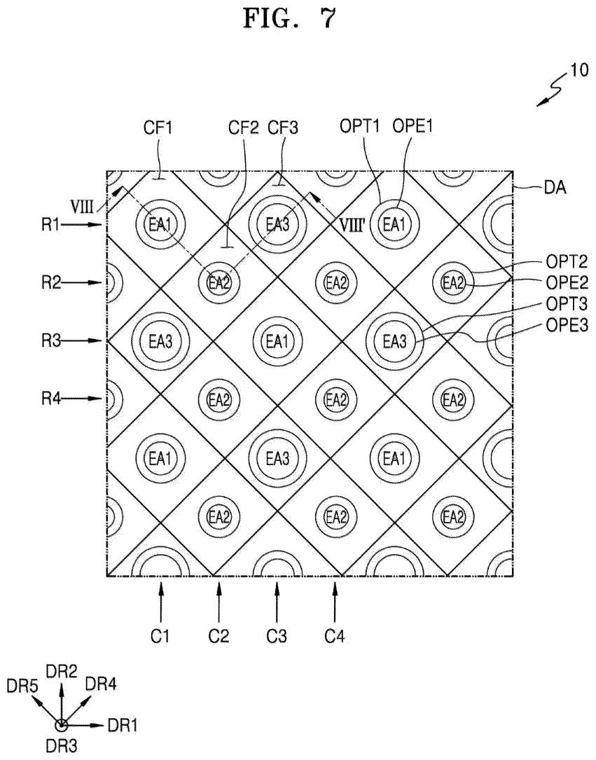

FIG. 7 is a plan view showing the arrangement of light-emitting regions and color filters of the display device of FIG. 5.

Referring to FIG. 7, the display device 10 may include a plurality of light-emitting areas EA1, EA2, and EA3 arranged in the display area DA.

The light-emitting areas EA1, EA2, and EA3 may include a first light-emitting area EA1, a second light-emitting area EA2, and a third light-emitting area EA3 that emit light of different colors. The first to third light-emitting areas EA1, EA2, and EA3 may emit red, green, or blue light, respectively, and the color of the light emitted from each light-emitting area EA1, EA2, or EA3 may vary depending on the type of light-emitting element arranged in the light-emitting element layer EML described below. In an embodiment, the first light-emitting area EA1 may emit red light, the second light-emitting area EA2 may emit green light, and the third light-emitting area EA3 may emit blue light. However, the disclosure is not limited thereto.

The plurality of light-emitting areas EA1, EA2, and EA3 may be arranged as a pentile type, e.g., a diamond pentile type. For example, the first light-emitting area EA1 and the third light-emitting area EA3 may be arranged spaced apart from each other in the first direction DR1, and may be arranged alternately in the first direction DR1 and the second direction DR2. In the arrangement of the light-emitting areas EA1, EA2, and EA3, the first light-emitting area EA1 and the third light-emitting area EA3 may be alternately arranged in the first direction DR1 in a first row R1 and a third row R3. In a first column C1 and a third column C3, the first light-emitting area EA1 and the third light-emitting area EA3 may be alternately arranged in the second direction DR2.

The second light-emitting area EA2 may be spaced apart from the adjacent second light-emitting area EA2 in the first direction DR1 and the second direction DR2, and may be spaced apart from the adjacent first light-emitting area EA1 and third light-emitting area EA3 in a fourth direction DR4 or a fifth direction DR5. A plurality of second light-emitting areas EA2 may be repeatedly arranged in the first direction DR1 and the second direction DR2, and the second light-emitting area EA2 and the first light-emitting area EA1, or the second light-emitting area EA2 and the third light-emitting area EA3 may be alternately arranged in the fourth direction DR4 or the fifth direction DR5. In the arrangement of the light-emitting areas EA1, EA2, and EA3, the second light-emitting areas EA2 may be repeatedly arranged in the first direction DR1 in a second row R2 and a fourth row R4, and the second light-emitting areas EA2 may be repeatedly arranged in the second direction DR2 in a second column C2 and a fourth column C4.

The first to third light-emitting areas EA1, EA2, and EA3 may be respectively defined by a plurality of openings OPE1, OPE2, and OPE3, each of which is formed in the pixel-defining film of the light-emitting element layer EML to be described later. For example, the first light-emitting area EA1 may be defined by the first opening OPE1 of the pixel-defining film, a second light-emitting area EA2 may be defined by the second opening OPE2 of the pixel-defining film, and the third light-emitting area EA3 may be defined by the third opening OPE3 of the pixel-defining film.

In an embodiment, the areas or sizes of the first to third light-emitting areas EA1, EA2, and EA3 may be different from each other. In an embodiment, the area of the third light-emitting area EA3 may be greater than the area of the first light-emitting area EA1 and the area of the second light-emitting area EA2, and the area of the first light-emitting area EA1 may be greater than the area of the second light-emitting area EA2. The areas of the light-emitting areas EA1, EA2, and EA3 may be determined by the sizes of the openings OPE1, OPE2, and OPE3 formed in the pixel-defining film. Depending on the areas of the light-emitting areas EA1, EA2, and EA3, the intensity of light emitted from the light-emitting areas EA1, EA2, and EA3 may vary, and by adjusting the areas of the light-emitting areas EA1, EA2, and EA3, the color of the image displayed on the display device 10 or the electronic device 1000 may be controlled. In an embodiment, the area of the third light-emitting area EA3 is the greatest, but the disclosure is not limited thereto. The areas of the light-emitting areas EA1, EA2, and EA3 may be adjusted depending on the color of the image desired in the display device 10 and the electronic device 1000. The areas of the light-emitting areas EA1, EA2, and EA3 may be related to light efficiency, lifespan of a light-emitting element ED, etc., and may be in a trade-off relationship with reflection by external light. The areas of the light-emitting areas EA1, EA2, and EA3 may be adjusted taking into consideration the foregoing factors.

The display device 10 having the arrangement of the light-emitting areas EA1, EA2, and EA3 as shown in FIG. 7 may form one pixel group which includes one first light-emitting area EA1, two second light-emitting areas EA2, and one third light-emitting area EA3 that are arranged adjacent to each other. One pixel group may represent white gradation by including the light-emitting areas EA1, EA2, and EA3 that emit light of different colors. However, the disclosure is not limited thereto, and a combination of the light-emitting areas EA1, EA2, and EA3 constituting one pixel group may be variously modified depending on the arrangement of the light-emitting areas EA1, EA2, and EA3 and the colors of light emitted through the light-emitting areas EA1, EA2, and EA3.

The display device 10 may include a plurality of color filters CF1, CF2, and CF3 arranged on the light-emitting areas EA1, EA2, and EA3. Each of the plurality of color filters CF1, CF2, and CF3 may be arranged to correspond to the light-emitting areas EA1, EA2, and EA3. For example, the color filters CF1, CF2, and CF3 may be arranged on a light-shielding layer BM including a plurality of holes OPT1, OPT2, and OPT3, each of which overlaps each of the corresponding light-emitting areas EA1, EA2, and EA3 or the openings OPE1, OPE2, and OPE3. That is to say, the holes OPT1, OPT2, and OPT3 of the light-shielding layer BM may be arranged to overlap the openings OPE1, OPE2, and OPE3 and form a light-outputting area through which light emitted from the light-emitting areas EA1, EA2, and EA3 is output. Each of the color filters CF1, CF2, and CF3 may have an area greater than the holes OPT1, OPT2, and OPT3 of the light-shielding layer BM and the openings OPE1, OPE2, and OPE3 of the pixel defining film PDL, and each of the color filters CF1, CF2, and CF3 may completely cover the light-outputting area formed by the holes OPT1, OPT2, and OPT3.

The color filters CF1, CF2, and CF3 may include a first color filter CF1, a second color filter CF2, and a third color filter CF3 arranged to respectively correspond to the different light-emitting areas EA1, EA2, and EA3. The color filters CF1, CF2, and CF3 may include a colorant, such as a dye or pigment, that absorbs light of a wavelength other than light of a specific wavelength, and may be arranged to correspond to the color of light emitted from the light-emitting area EA1, EA2, and EA3. For example, the first color filter CF1 may be a red color filter that is arranged to overlap the first light-emitting area EA1 and transmits red light. The second color filter CF2 may be a green color filter that is arranged to overlap the second light-emitting area EA2 and transmits green light, and the third color filter CF3 may be a blue color filter that is arranged to overlap the third light-emitting area EA3 and transmits blue light.

Similarly to the arrangement of the light-emitting areas EA1, EA2, and EA3, the color filters CF1, CF2, and CF3 may be arranged in a pentile type, e.g., a diamond pentile type. For example, the first color filter CF1 and the third color filter CF3 may be arranged alternately in the first direction DR1 and the second direction DR2. For example, the first color filter CF1 and the third color filter CF3 may be alternately arranged in the first direction DR1 in the first row R1 and the third row R3. In the first column C1 and the third column C3, the first color filter CF1 and the third color filter CF3 may be alternately arranged in the second direction DR2.

The second color filter CF2 may be spaced apart from other adjacent second color filters CF2 in the first direction DR1 and the second direction DR2, and may be spaced apart from the adjacent first color filter CF1 and third color filter CF3 in the fourth direction DR4 or the fifth direction DR5. The plurality of second color filters CF2 may be repeatedly arranged in the first direction DR1 and the second direction DR2, and the second color filter CF2 and the first color filter CF1, or the second color filter CF2 and the third color filter CF3 may be alternately arranged in the fourth direction DR4 or the fifth direction DR5. For example, the second color filters CF2 may be repeatedly arranged in the first direction DR1 in the second row R2 and the fourth row R4, and the second color filters CF2 may be repeatedly arranged in the second direction DR2 in the second column C2 and the fourth column C4.

According to an embodiment, the plurality of color filters CF1, CF2, and CF3 may be arranged to partially overlap other adjacent color filters CF1, CF2, and CF3. In FIG. 7, the adjacent color filters CF1, CF2, and CF3 are arranged to meet each other, but as will be described later, the adjacent color filters CF1, CF2, and CF3 may partially overlap at a boundary where they meet each other. FIG. 7 shows the arrangement of the color filters CF1, CF2, and CF3 viewed from top, and it may be understood that the edges of the color filters CF1, CF2, and CF3 arranged in a lower part among the overlapping color filters CF1, CF2, and CF3 may be covered by the color filters CF1, CF2, and CF3 arranged in an upper part. The overlapping portion where one color filter overlaps the other color filter among the color filters CF1, CF2, and CF3 may not overlap the light-emitting areas EA1, EA2, and EA3, and may be arranged to overlap with the light-shielding layer BM to be described later.

The display device 10 may reduce the intensity of reflected light due to external light by the overlapping arrangement of the color filters CF1, CF2, and CF3. The color of reflected light due to external light may be controlled by adjusting the arrangement, shape, and area of the color filters CF1, CF2, and CF3 on a plan view.

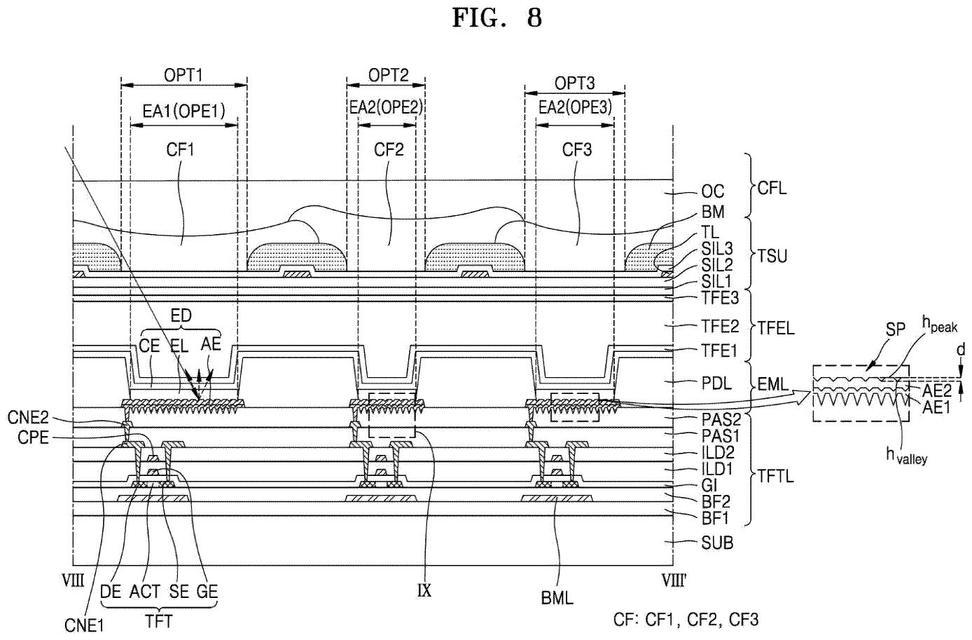

FIG. 8 is a cross-sectional view taken along a line VIII-VIII′ of FIG. 7. FIG. 8 shows a cross-section across the first light-emitting area EA1, the second light-emitting area EA2, and the third light-emitting area EA3. Each component in the cross-sectional view will be described in the order of manufacturing process of the display device.

The display panel 100 of the display device 10 may include a display layer (DU), a touch sensing layer TSU, and a color filter layer CFL. The display layer DU may include the substrate SUB, the thin film transistor layer TFTL, the light-emitting element layer EML, and the encapsulation layer TFEL. The color filter layer CFL of the display panel 100 may include the light-shielding layer BM arranged on the touch sensing layer TSU, and the color filters CF1, CF2, and CF3 of the color filter layer CFL may be arranged on the light-shielding layer BM.

The substrate SUB may be a base substrate or a base member. The substrate SUB may be a flexible substrate capable of bending, folding, rolling, etc. For example, the substrate SUB may include, but not limited to, a polymer resin such as polyimide (PI). For example, the substrate SUB may include a glass material or a metal material.

The thin film transistor layer TFTL may include a first buffer layer BF1, a lower metal layer BML, a second buffer layer BF2, a thin film transistor TFT, a gate insulation layer GI, a first interlayer insulation layer ILD1, a capacitor electrode CPE, a second interlayer insulation layer ILD2, a first connection electrode CNE1, a first passivation layer PAS1, a second connection electrode CNE2, and a second passivation layer PAS2.

The first buffer layer BF1 may be arranged on the substrate SUB. The first buffer layer BF1 may include an inorganic film capable of preventing the penetration of air or moisture. For example, the first buffer layer BF1 may include a plurality of inorganic films laminated alternately.

The lower metal layer BML may be arranged on the first buffer layer BF1. For example, the lower metal layer BML may be formed as a single layer or a plurality of layers including one or more of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing the penetration of air or moisture. For example, the second buffer layer BF2 may include a plurality of inorganic films laminated alternately.

The thin film transistor TFT may be formed in a pixel on the second buffer layer BF2. The thin film transistor TFT may be arranged on the second buffer layer BF2 and may form a pixel circuit of each of the plurality of pixels. For example, the thin film transistor TFT may be a driving transistor or a switching transistor in the pixel circuit. The thin film transistor TFT may include a semiconductor layer ACT, a source electrode SE, a drain electrode DE, and a gate electrode GE.

The semiconductor layer ACT may be arranged on the second buffer layer BF2. The semiconductor layer ACT may overlap the lower metal layer BML and the gate electrode GE in the thickness direction, and may be insulated from the gate electrode GE by the gate insulation layer GI.

The gate electrode GE may be arranged on the gate insulation layer GI. The gate electrode GE may overlap the semiconductor layer ACT with the gate insulation layer GI interposed therebetween.

The gate insulation layer GI may be arranged on the semiconductor layer ACT. For example, the gate insulation layer GI may cover the semiconductor layer ACT and the second buffer layer BF2, and may insulate the semiconductor layer ACT from the gate electrode GE. The gate insulation layer GI may include a contact hole through which the first connection electrode CNE1 passes.

The first interlayer insulation layer ILD1 may cover the gate electrode GE and the gate insulation layer GI. The first interlayer insulation layer ILD1 may include a contact hole through which the first connection electrode CNE1 passes. The contact hole of the first interlayer insulation layer ILD1 may be connected to the contact hole of the gate insulation layer GI and a contact hole of the second interlayer insulation layer ILD2.

The capacitor electrode CPE may be arranged on the first interlayer insulation layer ILD1. The capacitor electrode CPE may overlap the gate electrode GE in the thickness direction. The capacitor electrode CPE and the gate electrode GE may form a capacitance.

The second interlayer insulation layer ILD2 may cover the capacitor electrode CPE and the first interlayer insulation layer ILD1. The second interlayer insulation layer ILD2 may include a contact hole through which the first connection electrode CNE1 passes. The contact hole of the second interlayer insulation layer ILD2 may be connected to the contact hole of the first interlayer insulation layer ILD1 and the contact hole of the gate insulation layer GI.

The first connection electrode CNE1 may be arranged on the second interlayer insulation layer ILD2. The first connection electrode CNE1 may electrically connect the drain electrode DE of the thin film transistor TFT to the second connection electrode CNE2. The first connection electrode CNE1 may extend through the contact holes formed in the second interlayer insulation layer ILD2, the first interlayer insulation layer ILD1, and the gate insulation layer GI to contact the drain electrode DE of the thin film transistor TFT.

The first passivation layer PAS1 may cover the first connection electrode CNE1 and the second interlayer insulation layer ILD2. The first passivation layer PAS1 may be formed on the thin film transistor TFT to protect the thin film transistor TFT. The first passivation layer PAS1 may include a contact hole through which the second connection electrode CNE2 passes. The first passivation layer PAS1 may include an organic material such as, for example but not limited to, acrylic, benzocyclobutene (BCB), hexamethyldisiloxane (HMDSO), etc.

The second connection electrode CNE2 may be arranged on the first passivation layer PAS1. The second connection electrode CNE2 may electrically connect the first connection electrode CNE1 to a pixel electrode AE of the light-emitting element ED. The second connection electrode CNE2 may extend through the contact hole formed in the first passivation layer PAS1 to come into contact with the first connection electrode CNE1.

The second passivation layer PAS2 may be arranged on the second connection electrode CNE2 and the first passivation layer PAS1 to cover the first passivation layer PAS1. The second passivation layer PAS2 may include a contact hole through which the pixel electrode AE of the light-emitting element ED passes. The second passivation layer PAS2 may include the same organic material as the first passivation layer PAS1, such as acrylic, benzocyclobutene (BCB), hexamethyldisiloxane (HMDSO), etc. A top surface of the second passivation layer PAS2 may be flat, but may have a surface pattern at least in a portion corresponding to the pixel electrode AE, as shown in FIG. 8. The top surface of the second passivation layer PAS2 will be described in detail later.

The light-emitting element layer EML may be arranged on the thin film transistor layer TFTL. The light-emitting element layer EML may include the light-emitting element ED and a pixel-defining film PDL. The light-emitting element ED may include the pixel electrode AE, the light-emitting layer EL, and the common electrode CE.

The pixel electrode AE may be arranged on the second passivation layer PAS2. The pixel electrode AE may be arranged to overlap any one of the openings OPE1, OPE2, and OPE3 of the pixel-defining film PDL. The pixel electrode AE may be electrically connected to the drain electrode DE of the thin film transistor TFT through the first and second connection electrodes CNE1 and CNE2.

According to an embodiment, the pixel electrode AE may include a reflective electrode AE1 arranged at least on the second passivation layer PAS2 and a transparent electrode AE2 arranged on the reflective electrode AE1. The reflective electrode AE1 may include a metal having high reflectance. The reflective electrode AE1 may include a metal such as aluminum (Al) or silver (Ag). The transparent electrode AE2 may include a light-transmissive conductive metal oxide. The transparent electrode may include a metal oxide such as an indium tin oxide (ITO), an indium oxide (In₂O₃), or an indium zinc oxide (IZO). However, the disclosure is not limited thereto, and the pixel electrode AE may further include a lower transparent electrode (not shown) including a light-transmissive conductive metal oxide under the reflective electrode AE1, such that the pixel electrode AE may have a three-layer structure such as ITO/Ag/ITO, ITO/Al/ITO, IZO/Ag/ITO, IZO/Al/ITO, In₂O₃/Ag/ITO, In₂O₃/Al/ITO, etc.

A surface pattern SP may be provided on the surface of the pixel electrode AE facing the color filter layer CFL. According to an embodiment, the display device 10 may have a POL-less structure, which means that the display device 10 does not include a polarization plate. For the display device 10 having a POL-less structure, the color filter layer CFL may be applied instead of a polarization plate. However, the color filter layer CFL included in the display device 10 of the disclosure may increase the visibility of the existing diffraction pattern of the pixel electrode AE compared to the conventional polarization plate. This is because, although light is absorbed by the light-shielding layer BM included in the color filter layer CFL, the light that passes through the color filters CF is dispersed, reflected by the pixel electrode AE, and then output from the display device 10 again. The display device 10 according to an embodiment includes the surface pattern SP on the top surface of the pixel electrode AE to increase roughness, thereby improving diffraction visibility by reflected light through a scattering effect.

An index representing the roughness characteristics of the surface pattern SP of the pixel electrode AE may be expressed as a peak-to-valley d of FIG. 8. In an embodiment, the peak-to-valley d may be defined as a height difference (d=hₚₑₐₖ−h_{valley}) between the highest point (peak) hₚₑₐₖ and the lowest point (valley) h_{valley} in the surface pattern SP. In another example, the peak-to-valley d may be defined as a difference between the average height of protruding points (peak points) of the surface pattern SP and the average height of concave points (valley points) of the surface pattern SP in each measurement section.

The peak-to-valley d of the surface pattern SP of the pixel electrode AE may be in a range of about 30 nanometers to about 50 nanometers. When the peak-to-valley d of the surface pattern SP is less than about 30 nanometers, the diffraction visibility by reflected light may not be improved due to the minimal scattering effect. In contrast, when the peak-to-valley d of the surface pattern SP exceeds about 50 nanometers, a phase difference may occur and thus diffraction may increase when external light is incident on and reflected by the pixel electrode AE. A micrometer-size surface pattern on the pixel electrode AE may worsen the visibility of the refractive diffraction. A specific shape, arrangement, and manufacturing method of the surface pattern SP will be described later.

The pixel-defining film PDL may be formed on a portion of the pixel electrode AE. The pixel-defining film PDL may be arranged on the second passivation layer PAS2 and a portion of the pixel electrode AE, and may include the plurality of openings OPE1, OPE2, and OPE3 that extends to the remaining portion of the pixel electrode AE. That is to say, the pixel-defining film PDL may include the first opening OPE1, the second opening OPE2, and the third opening OPE3, and each of the openings OPE1, OPE2, and OPE3 may extend to a portion of the pixel electrode AE which is not covered by the pixel defining film PDL. As described above, each of the openings OPE1, OPE2, and OPE3 of the pixel-defining film PDL may define the first to third light-emitting areas EA1, EA2, and EA3, and the areas or sizes of the first to third light-emitting areas EA1, EA2, and EA3 may be different from each other. The pixel-defining film PDL may separate and insulate the pixel electrode AE of each of the plurality of light-emitting elements ED from other pixel electrodes AE of adjacent light emitting elements ED. The pixel-defining film PDL may include a light-absorbing material to prevent light reflection. For example, the pixel-defining film PDL may include a polyimide (PI)-based binder and a pigment mixed with red, green, and blue. The pixel-defining film PDL may include a mixture of a cardo-based binder resin, a lactam black pigment, and a blue pigment. The pixel-defining film PDL may include carbon black.

The light-emitting layer EL may be arranged on the pixel electrode AE. The light-emitting layer EL may be arranged in an opening of the pixel-defining film PDL and correspond to each light-emitting area EA1, EA2, and EA3. For example, the light-emitting layer EL may be an organic light-emitting layer including an organic material, but the disclosure is not limited thereto. For the light-emitting layer EL including an organic light-emitting layer, when the thin film transistor TFT applies a voltage to the pixel electrode AE of the light-emitting element ED and the common electrode CE of the light-emitting element ED receives a common voltage or cathode voltage, holes and electrons may move to the light-emitting layer EL through a hole transporting layer and an electron transporting layer, respectively, and the holes and electrons may be combined with each other in the light-emitting layer EL to emit light.

The common electrode CE may be arranged on the light-emitting layer EL. The common electrode CE may be formed to cover the top surface of the light-emitting layer EL. For example, the common electrode CE may be arranged to cover at least the display area DA of the display device 10. The common electrode CE may be arranged on the light-emitting layer EL in the first to third light-emitting areas EA1, EA2, and EA3, and may be arranged on the pixel-defining film PDL. The common electrode CE may include, but not limited to, a transparent conductive material to improve light extraction efficiency.

The common electrode CE may receive a common voltage, which may be referred to as a low-potential voltage, a second voltage, or an ELVDD. When the pixel electrode AE receives a voltage corresponding to the data voltage and the common electrode CE receives a low-potential voltage, a potential difference may be formed between the pixel electrode AE and the common electrode CE, causing the light-emitting layer EL to emit light.

The encapsulation layer TFEL may be arranged on the common electrode CE and cover the plurality of light-emitting elements ED. The encapsulation layer TFEL may include at least one inorganic film to prevent oxygen or moisture from penetrating into the light-emitting element layer EML. The encapsulation layer TFEL may include at least one organic film to protect the light-emitting element layer EML from foreign substances such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 arranged between the first encapsulation layer TFE1 and the second encapsulation layer TFE2 may be an organic encapsulation layer.

The touch sensing layer TSU may be arranged on the encapsulation layer TFEL. The touch sensing layer TSU may have insulating and optical functions. The touch sensing layer TSU may sequentially include a first touch insulation layer SIL1, a second touch insulation layer SIL2, a touch electrode TL, and a third touch insulation layer SIL3 in the direction from the encapsulation layer TFEL to the color filter layer CFL.

The light-shielding layer BM of the color filter layer CFL may be arranged on the touch sensing layer TSU. The light-shielding layer BM may be arranged to overlap the pixel-defining film, and may include the plurality of holes OPT1, OPT2, and OPT3 overlapping the light-emitting areas EA1, EA2, and EA3. For example, the first hole OPT1 may be arranged to overlap the first light-emitting area EA1 or the first opening OPE1. The second hole OPT2 may be arranged to overlap the second light-emitting area EA2 or the second opening OPE2, and the third hole OPT3 may be arranged to overlap the third light-emitting area EA3 or the third opening OPE3. The area or size of each of the holes OPT1, OPT2, and OPT3 may be greater than the area or size of each of the openings OPE1, OPE2, and OPE3 of the pixel-defining film PDL. As the holes OPT1, OPT2, and OPT3 of the light-shielding layer BM are formed larger than the openings OPE1, OPE2, and OPE3 of the pixel-defining film PDL, the light emitted from the light-emitting areas EA1, EA2, and EA3 may be viewed by the user from the side as well as the front of the display device 10.

The light-shielding layer BM may include a light-absorbing material. For example, the light-shielding layer BM may include an inorganic black pigment or an organic black pigment. The inorganic black pigment may include carbon black, and the organic black pigment may include, but not limited to, at least one of lactam black, perylene black, and aniline black. The light-shielding layer BM may improve the color reproducibility of the display device 10 by preventing external visible light from penetrating into the first to third light-emitting areas EA1, EA2, and EA3 and causing color mixing.

The color filters CF1, CF2, and CF3 of the color filter layer CFL may be arranged on the light-shielding layer BM. The different color filters CF1, CF2, and CF3 may be arranged to correspond to the different light-emitting areas EA1, EA2, and EA3 (or openings OPE1, OPE2, and OPE3) and the different holes OPT1, OPT2, and OPT3 of the light-shielding layer BM, respectively. For example, the first color filter CF1 may be arranged to correspond to the first light-emitting area EA1 (or the first opening OPE1), the second color filter CF2 may be arranged to correspond to the second light-emitting area EA2 (or the second opening OPE2), and the third color filter CF3 may be arranged to correspond to the third light-emitting area EA3 (or the third opening OPE3). The first color filter CF1 may be arranged in the first hole OPT1 of the light-shielding layer BM, the second color filter CF2 may be arranged in the second hole OPT2 of the light-shielding layer BM, and the third color filter CF3 may be arranged in the third hole OPT3 of the light-shielding layer BM. Each of the color filters CF1, CF2, and CF3 may have a greater area in the plan view than the holes OPT1, OPT2, and OPT3 of the light-shielding layer BM, and a portion of each of the color filters CF1, CF2, and CF3 may be arranged directly on the light-shielding layer BM.

A planarization layer OC of the color filter layer CFL may be arranged on the color filters CF1, CF2, and CF3 and the light-shielding layer BM, so as to planarize the top of the color filters CF1, CF2, and CF3. The planarization layer OC may be a colorless, light-transmissive layer that does not represent a color in a visible spectrum. For example, the planarization layer OC may include a colorless, light-transmissive organic material, such as an acrylic resin.

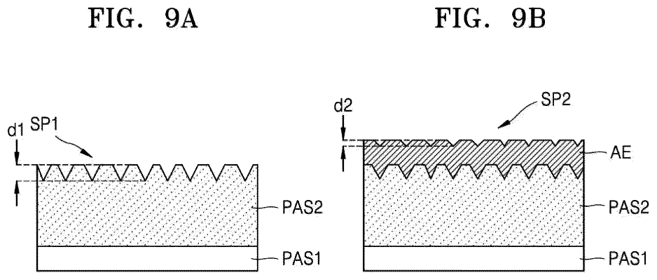

FIG. 9 is an enlarged cross-sectional view of a portion IX of FIG. 8 and illustrates a surface pattern of a pixel electrode and a method of forming the same according to an embodiment.

Hereinafter, a first surface pattern SP1 refers to a passivation layer surface pattern provided on the second passivation layer PAS2, and a second surface pattern SP2 refers to an electrode surface pattern provided on the pixel electrode AE.

Referring to FIG. 9, the first surface pattern SP1 may be a groove pattern including a dented portion. A peak-to-valley d1 of the first surface pattern SP1 may be less than about 100 nanometers. The peak-to-valley d1 of the first surface pattern SP1 may be in a range of about 50 nanometers to about 100 nanometers. When the peak-to-valley d1 of the first surface pattern SP1 is less than about 50 nanometers, the second surface pattern SP2 may not be formed on the pixel electrode AE. When the peak-to-valley d1 of the first surface pattern SP1 exceeds about 100 nanometers, the roughness of the second surface pattern SP2 formed by following the first surface pattern SP1 increases, causing the increase of the diffraction.

As shown in FIG. 9A, the first surface pattern SP1 may be formed using an imprint method. In detail, the first surface pattern SP1 may be formed using a nano-imprint method in which a mold having a pattern corresponding to the first surface pattern SP1 is brought into contact with the second passivation layer PAS2 to imprint the pattern of the mold on the second passivation layer PAS2. The nano-imprint method has no limitations on the wavelength of light, thus it is advantageous in implementing ultra-fine patterns at the scale of several tens of nanometers. In addition, as the nano-imprint method does not require optical equipment, a pattern may be formed more simply and at a lower cost than a photolithography method.

Next, as shown in FIG. 9B, the pixel electrode AE may be formed on the second passivation layer PAS2 on which the first surface pattern SP1 is formed. The pixel electrode AE may be formed by deposition. The second surface pattern SP2 may be formed on the pixel electrode AE following the first surface pattern SP1. A peak-to-valley d2 of the second surface pattern SP2 may be in a range of about 30 nanometers to about 50 nanometers, which is smaller than the peak-to-valley d1 of the first surface pattern SP1.

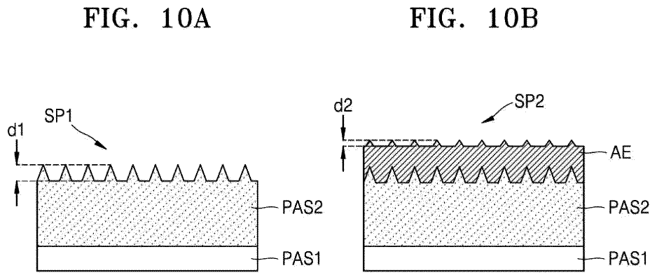

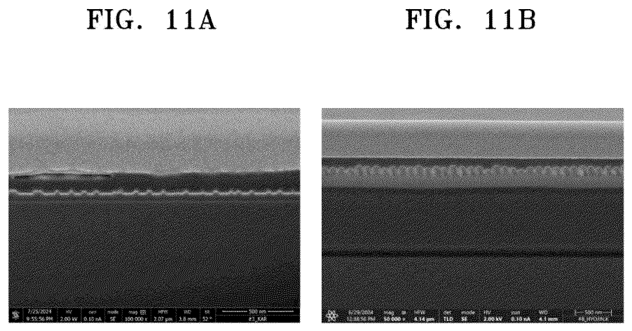

FIG. 10 is a cross-sectional view showing a surface pattern of a pixel electrode and a method of forming the same according to an embodiment.

According to an embodiment of FIG. 10, the first surface pattern SP1 may be a rib pattern including a protruding portion. The manufacturing method, structure, and characteristics of the first surface pattern SP1 and the second surface pattern SP2 shown in FIG. 10 are the same as those described in FIG. 9, and thus a redundant description will be omitted.

FIG. 11 shows photographs of a first surface pattern and a second surface pattern according to the embodiment of FIG. 10.

FIG. 11A shows that a first surface pattern is formed on a top surface of a second passivation layer using an imprint method, as depicted in FIG. 10A. FIG. 11B shows that a metal layer is formed on a top surface of a first surface pattern, as depicted in FIG. 10B. Referring to FIG. 11B, it may be seen that the second surface pattern of the metal layer is formed following the first surface pattern.

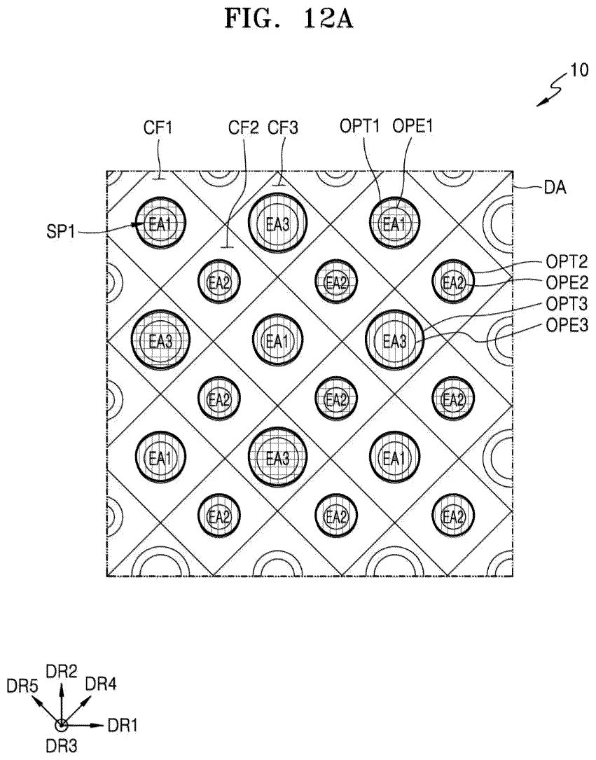

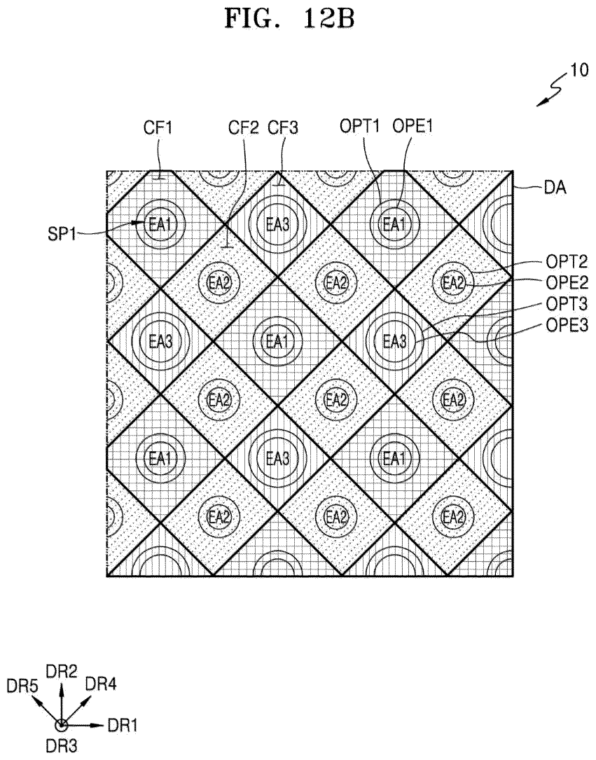

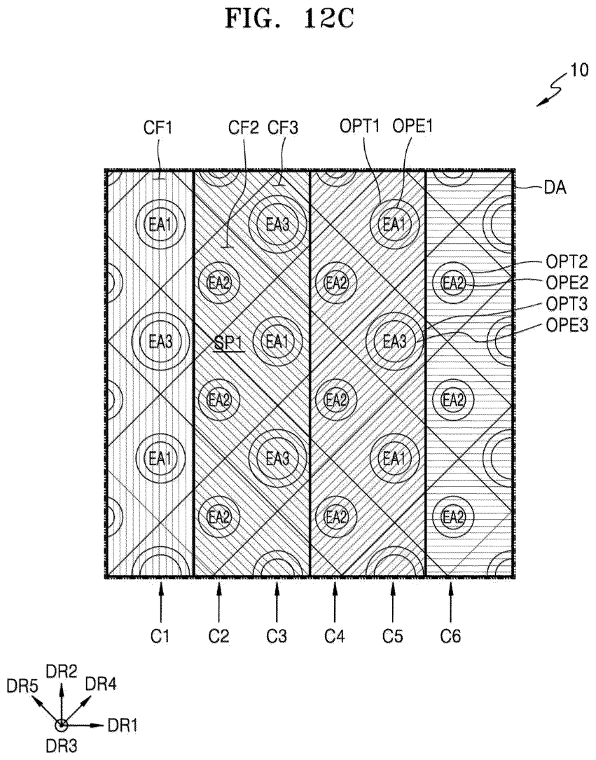

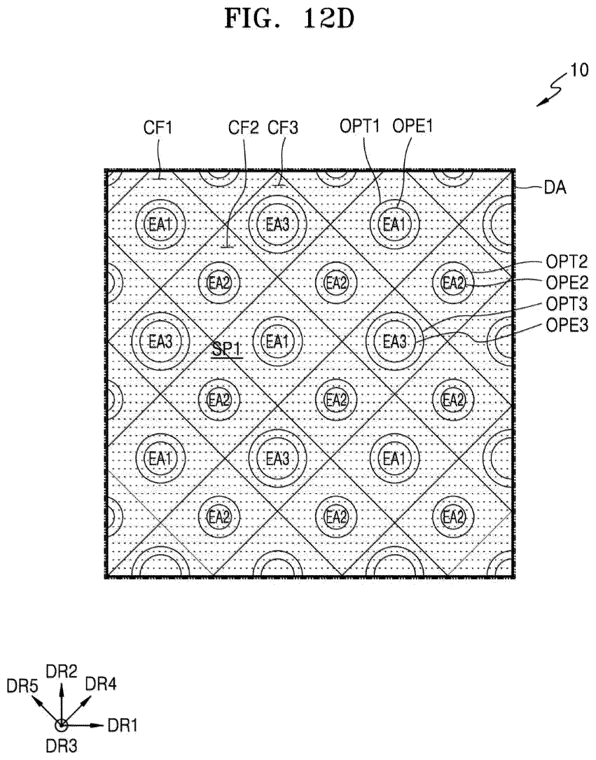

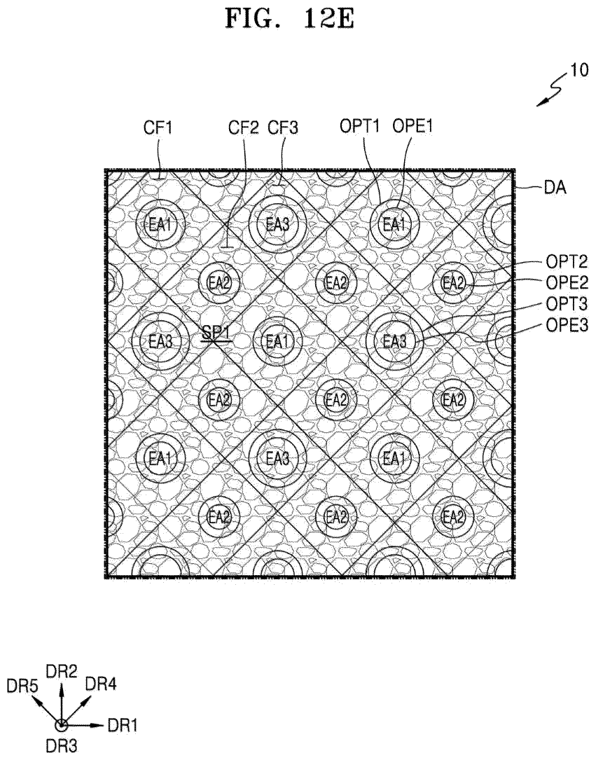

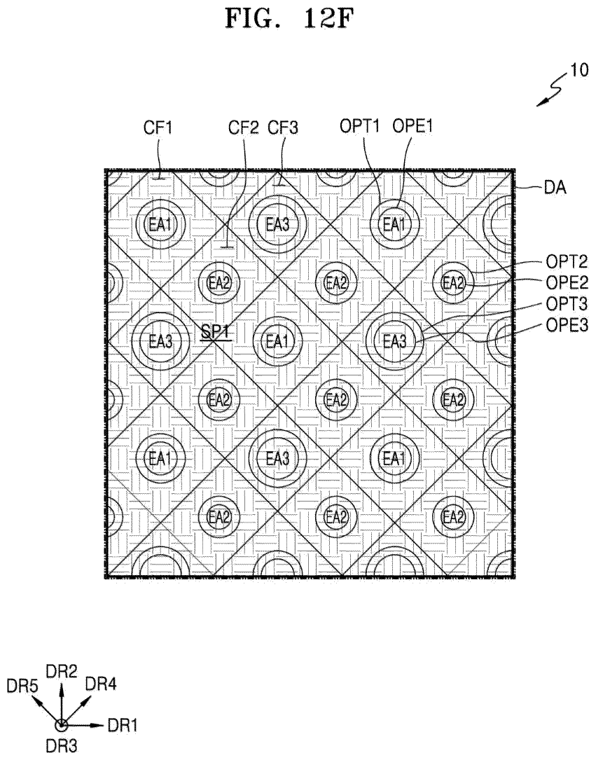

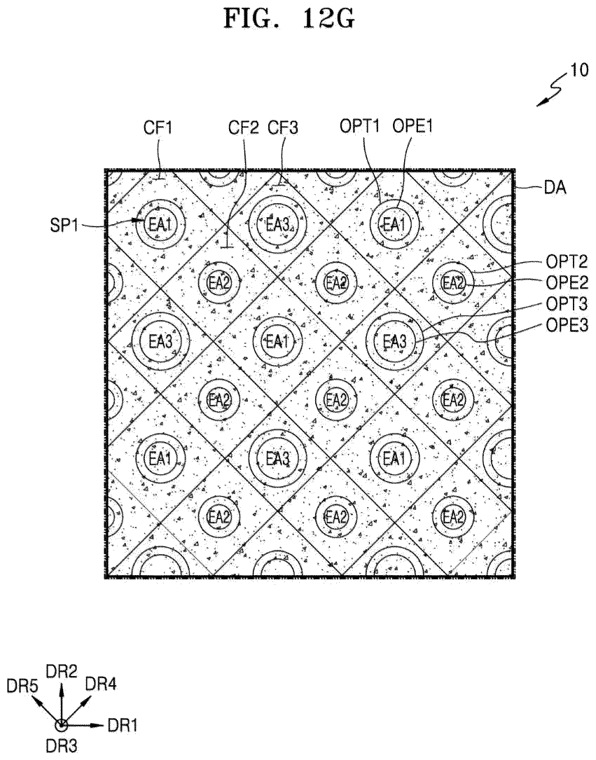

FIGS. 12A to 12G are plan views showing various shapes and arrangements of the first surface pattern described in FIG. 7. FIGS. 12A to 12G are plan views showing not only the arrangement of light-emitting areas and color filters of the display device of FIG. 7, but also a first surface pattern formed on a second passivation layer.

The first surface pattern SP1 may be provided on the second passivation layer PAS2 corresponding to at least the light-emitting areas EA1, EA2, and EA3. As shown in FIG. 8, the first surface pattern SP1 may be formed on the second passivation layer PAS2 in a region corresponding to the light-emitting areas EA1, EA2, and EA3. However, the disclosure is not limited thereto. For example, as shown in FIG. 12A, the first surface pattern SP1 may be formed on the second passivation layer PAS2 in a region corresponding to the holes OPT1, OPT2, and OPT3 of the light-shielding layer. For example, as shown in FIG. 12B, the first surface pattern SP1 may be formed on the second passivation layer PAS2 in a region corresponding to the color filters CF1, CF2, and CF3. For example, as shown in FIGS. 12C to 12G, the first surface pattern SP1 may be formed on the entire surface of the second passivation layer PAS2 corresponding to the display area DA.

The first surface pattern SP1 may have various shapes and various arrangements. The first surface pattern SP1 may have a periodic pattern. For example, the first surface pattern SP1 may have at least one of a dot pattern, a line pattern, or a grid pattern.

As shown in FIG. 12A, the first surface pattern SP1 may have a shape in which a grid pattern and a line pattern are randomly arranged on the second passivation layer PAS2 in a region corresponding to the holes OPT1, OPT2, and OPT3 of the light-shielding layer. As shown in FIG. 12B, the first surface pattern SP1 may have a shape in which a dot pattern, a line pattern, and a grid pattern are arranged on the second passivation layer PAS2 in a region corresponding to the color filters CF1, CF2, and CF3 in order for each of the light-emitting areas EA1, EA2, and EA3 to have a different pattern. For example, the first light-emitting area EA1 may include the grid pattern, the second light-emitting area EA2 may include the dot pattern, and the third light-emitting area EA3 may include the line pattern. As shown in FIG. 12C, the first surface pattern SP1 may have various line patterns that are randomly arranged on the second passivation layer PAS2 corresponding to pixels arranged in columns. For example, pixels in a first column C1 may include a vertical line pattern, pixels in a second column C2 and a third column C3 may include a right diagonal line pattern, pixels in a fourth column C4 and a fifth column C5 may include a left diagonal line pattern, and pixels in a sixth column C6 may include a horizontal line pattern. As shown in FIG. 12D, the first surface pattern SP1 may be provided as a dot pattern on the entire surface of the second passivation layer PAS2 corresponding to the display area DA.

The first surface pattern SP1 may have a non-periodic pattern. For example, the first surface pattern SP1 may have an arbitrary random pattern shape, a non-periodic pattern shape having no repetitive period, or a random number pattern shape that is randomly arranged. As the first surface pattern SP1 has a non-periodic pattern, an interference phenomenon occurring at specific wavelengths may be reduced, allowing light to be evenly distributed at various angles and wavelengths.

As shown in FIG. 12E, the first surface pattern SP1 may have a random pattern shape on the entire surface of the second passivation layer PAS2 corresponding to the display area DA. The random pattern shape may be a pattern including elements that are arranged completely irregularly. As shown in FIG. 12F, the first surface pattern SP1 may have a non-periodic pattern shape on the entire surface of the second passivation layer PAS2 corresponding to the display area DA. The non-periodic pattern shape may be a pattern that has a regular structure but is repeated without a specific period. As shown in FIG. 12G, the first surface pattern SP1 may have a random number pattern shape on the entire surface of the second passivation layer PAS2 corresponding to the display area DA. The random number pattern may be a pattern showing a texture such as noise or grain.

The embodiments shown in FIGS. 12A to 12G are examples, and the disclosure is not limited thereto, and surface patterns may be implemented in various combinations.

Although the first surface pattern SP1 on the second passivation layer PAS2 is described in FIGS. 12A to 12G, the second surface pattern SP2 on the pixel electrode AE is formed following the first surface pattern SP1, such that the second surface pattern SP2 may also have various shapes like the first surface pattern SP1. The second surface pattern SP2 may also have at least one of a dot pattern, a line pattern, or a grid pattern, and may have an arbitrary random pattern shape, a non-periodic pattern shape having no repetitive period, or a randomly arranged random number pattern shape. A redundant description thereof will be omitted.

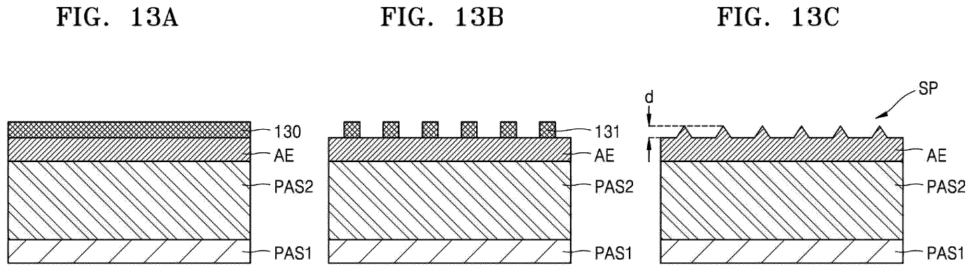

FIG. 13 is a cross-sectional view showing a surface pattern of a pixel electrode and a method of forming the same according to an embodiment. The surface pattern SP according to an embodiment of FIG. 13 is formed directly on the pixel electrode AE without forming the first surface pattern SP1 on the second passivation layer PAS2. Hereinafter, the surface pattern refers to the surface pattern SP formed on the pixel electrode AE.

Referring to FIG. 13, the surface pattern SP may be a rib pattern including a protruding portion. The peak-to-valley d of the surface pattern SP may be in a range of about 30 nanometers to about 50 nanometers.

As shown in FIG. 13, the surface pattern SP may be formed using an imprint method. Referring to FIG. 13A, an organic material layer 130 may be formed on the pixel electrode AE. The organic material layer 130 may include an organic acrylic resin. Referring to FIG. 13B, a mold having a pattern corresponding to the surface pattern SP may be brought into contact with the organic material layer 130 using the nanoimprint method to imprint the pattern of the mold on the pixel electrode AE. An imprint pattern 131 made of an organic material layer may be transferred onto the pixel electrode AE. As shown in FIG. 13C, the surface pattern SP may be directly formed on the pixel electrode AE through an ashing process based on the imprint pattern 131 made of an organic material. The imprint pattern 131 may be completely removed from the pixel electrode AE, and portions of the top surface of the pixel electrode AE that are not covered by the imprint pattern 131 may be etched, thereby forming the surface pattern SP directly on the pixel electrode AE.

The display device according to an embodiment may be applied to various electronic devices. An electronic device according to an embodiment may include the display device described above, and may further include a module or device having additional functions in addition to the display device 10.

FIG. 14 is a block diagram of an electronic device according to an embodiment. Referring to FIG. 14, an electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The controller may output various control signals necessary for driving the display module 1100. For example, the controller may apply various signals to a plurality of pixels of a display module 1100. The controller may transmit a scan control signal to the scan driver 210, and causes the scan driver 210 to output scan signals to the pixels in response to the scan control signal. The controller may transmit a control signal to the data driver of the display driving unit 200, and the data driver may convert image data into an analog voltage (e.g., a data voltage) in response to the control signal and output the data voltage to the pixels.

The memory 1300 may store data information necessary for the operation of the processor 1200 or the display module 1100. When the processor 1200 executes an application stored in the memory 1300, an image data signal and/or an input control signal may be transmitted to the display module 1100, and the display module 1100 may process the received signal and display the image information through a display screen.

The power module 1400 may include a power supply module, such as a power adapter, a battery device, etc., and a power conversion module that converts power supplied by the power supply module to generate power required for the operation of the electronic device 1000. For example, the power module 1400 may supply power to the controller, enabling the controller to operate.

At least one of the components of the electronic device 1000 may be included in the display device according to the above-described embodiments. Some of the individual modules functionally included in a module may be included in the display device and others may be provided separately from the display device. For example, the display device may include the display module 1100, and the processor 1200, the memory 1300, and the power module 1400 may be provided in the form of other devices in the electronic device 1100 other than the display device.

FIG. 15 is a schematic diagram of an electronic device according to various embodiments.

Referring to FIG. 15, various electronic devices to which the display device according to embodiments is applied may include not only image display electronic devices such as a smart phone 1000_1a, a tablet PC 1000_1b, a laptop computer 1000_1c, a TV 1000_1d, a desk monitor 1000_1e, etc., but also wearable electronic devices including display modules such as smart glasses 1000_2a, a head mounted display 1000_2b, a smart watch 1000_2c, etc., and vehicle electronic devices 1000_3 including display modules such as an instrument panel, a center fascia, a center information display (CID) arranged on a dashboard, a room mirror display, etc., of vehicles.

A display device, a method of manufacturing the display device, and an electronic device including the display device according to embodiments may provide a highly visible and visually clear screen. However, the scope of the disclosure is not limited by these effects.

While some embodiments have been described, it will be readily apparent to those of skill in the art that various modifications may be made thereto without departing from the spirit and scope of the disclosure. Unless otherwise stated, the description of characteristics or aspects in each embodiment should generally be considered to be applicable to other similar characteristics or aspects of other embodiments. Accordingly, as will be apparent to those of ordinary skill in the art, characteristics or components described in connection with a particular embodiment may be combined with characteristics or components described in connection with other embodiments. Therefore, the foregoing description should not be construed as limited to the specific embodiments disclosed herein, but should be understood to be intended for combination with or application to other embodiments. Accordingly, the true technical scope of the disclosure should be defined by the technical spirit of the appended claims.

What is claimed is:

1. A display device comprising:
a plurality of pixels arranged on a substrate;
a thin film transistor arranged in each of the plurality of pixels;
a passivation layer covering the thin film transistor;
a pixel-defining film defining a plurality of light-emitting areas and comprising a light-absorbing material, wherein each of the plurality of pixels includes at least one light-emitting area;
a light-emitting element comprising a pixel electrode arranged on the passivation layer corresponding to the plurality of light-emitting areas defined by the pixel-defining film;
an encapsulation layer sealing the light-emitting element; and
a color filter layer overlapping the plurality of light-emitting area and comprising at least one color filter arranged on the encapsulation layer,
wherein a top surface of the pixel electrode includes an electrode surface pattern, and a peak-to-valley of the electrode surface pattern is in a range from about 30 nanometers to about 50 nanometers.

2. The display device of claim 1, wherein a top surface of the passivation layer corresponding to the plurality of light-emitting areas includes a passivation layer surface pattern, and the electrode surface pattern provided on the top surface of the pixel electrode follows the passivation layer surface pattern, and
a peak-to-valley of the passivation layer surface pattern is in a range from about 50 nanometers to about 100 nanometers.

3. The display device of claim 2, wherein an entire top surface of the passivation layer includes the passivation layer surface pattern.

4. The display device of claim 2, wherein the passivation layer surface pattern comprises, on the top surface of the passivation layer, a different pattern shape for each of the pixels arranged in rows or columns, or a different pattern shape for each of the plurality of light-emitting areas.

5. The display device of claim 2, wherein the passivation layer surface pattern and the electrode surface pattern includes groove patterns comprising a dented portion, or rib patterns comprising a protruding portion.

6. The display device of claim 2, wherein each of the passivation layer surface pattern and the electrode surface pattern comprise at least one of a dot pattern, a line pattern, or a grid pattern.

7. The display device of claim 2, wherein each of the passivation layer surface pattern and the electrode surface pattern have an arbitrary random pattern shape, a non-periodic pattern shape having no repetitive period, or a randomly arranged random number pattern shape.

8. The display device of claim 1, wherein a top surface of the passivation layer is flat, and the pixel electrode having the electrode surface pattern is arranged on the passivation layer having the flat top surface.

9. The display device of claim 1, wherein the pixel electrode comprises a reflective electrode comprising a metal having a high reflectance arranged on the passivation layer, and a transparent electrode comprising a conductive metal oxide arranged on the reflective electrode.

10. The display device of claim 1, wherein the passivation layer comprises:
a first passivation layer covering the thin film transistor and comprising an organic material; and
a second passivation layer arranged on the first passivation layer and comprising an organic material, and
wherein the pixel electrode is arranged on a top surface of the second passivation layer.

11. The display device of claim 1, further comprising a touch sensing layer comprising a touch electrode between the encapsulation layer and the color filter layer.

12. The display device of claim 1, wherein the color filter layer further comprises:
a light-shielding layer overlapping the pixel-defining film and comprising a hole corresponding to the color filter; and
a planarization layer covering the color filter and the light-shielding layer, comprising an organic material, and planarizing a top surface of the color filter.

13. A method of manufacturing a display device, comprising:
forming a thin film transistor in each of a plurality of pixels arranged on a substrate;
forming a passivation layer covering the thin film transistor;
forming a pixel electrode comprising an electrode surface pattern and arranged on the passivation layer corresponding to a light-emitting area;
forming a pixel-defining film comprising a light-absorbing material and arranged on the passivation layer to define the light-emitting area;
forming a light-emitting layer on the pixel electrode corresponding to the light-emitting area;
forming a common electrode covering a top surface of the light-emitting layer;
forming an encapsulation layer sealing a light-emitting element comprising the pixel electrode, the light-emitting layer, and the common electrode; and
forming a color filter layer comprising at least one color filter overlapping the light-emitting area and arranged on the encapsulation layer,
wherein a peak-to-valley of the electrode surface pattern is in a range from about 30 nanometers to about 50 nanometers.

14. The method of claim 13, wherein the forming of the pixel electrode comprising the electrode surface pattern comprises:
forming a passivation layer surface pattern using an imprint method on the passivation layer corresponding to the light-emitting area; and
forming the electrode surface pattern of the pixel electrode using the passivation layer surface pattern on the passivation layer corresponding to the light-emitting area.

15. The method of claim 14, wherein the forming of the passivation layer surface pattern comprises contacting a mold comprising a pattern corresponding to the passivation layer surface pattern with a top surface of the passivation layer and imprinting the pattern of the mold on the top surface of the passivation layer, and
a peak-to-valley of the passivation layer surface pattern is in a range from about 50 nanometers to about 100 nanometers.

16. The method of claim 14, wherein the passivation layer surface pattern is formed on an entire top surface of the passivation layer.

17. The method of claim 14, wherein the forming of the passivation layer surface pattern comprises forming, on a top surface of the passivation layer, a different pattern shape for each of the pixels arranged in a row or a column, or a different pattern shape for each light-emitting area.

18. An electronic device comprising:
a pixel circuit arranged in a pixel on a substrate and comprising a thin film transistor;
a passivation layer covering the thin film transistor;
a pixel-defining film defining a light-emitting area and comprising a light-absorbing material;
a light-emitting element comprising a pixel electrode arranged on the passivation layer corresponding to the light-emitting area defined by the pixel-defining film;
an encapsulation layer sealing the light-emitting element;
a color filter layer comprising at least one color filter arranged on the encapsulation layer and overlapping the light-emitting area;
a controller configured to apply a signal to the pixel circuit; and
a power module configured to apply power to the controller,
wherein a top surface of the pixel electrode includes an electrode surface pattern, and a peak-to-valley of the electrode surface pattern is in a range from about 30 nanometers to about 50 nanometers.

19. The electronic device of claim 18, wherein a top surface of the passivation layer corresponding to the light-emitting area includes a passivation layer surface pattern, and the electrode surface pattern provided on the top surface of the pixel electrode follows the passivation layer surface pattern, and
a peak-to-valley of the passivation layer surface pattern is in a range from about 50 nanometers to about 100 nanometers.

20. The electronic device of claim 19, wherein an entire top surface of the passivation layer includes the passivation layer surface pattern.
